(19) United States
(12) Patent Application Publication
(10) Pub. No.: US 2010/0145660 A1
(43) Pub. Date: Jun. 10, 2010

(54) MEMS SENSOR WITH BUILT-IN SELF-TEST

(75) Inventors: Christoph Lang, Cupertino, CA (US); Valdimir Petkov, Mountain View, CA (US); Udo-Martin Gomez, Leonberg (DE)

Correspondence Address: MAGINOT, MOORE & BECK, LLP;CHASE TOWER, 111 MONUMENT CIRCLE, SUITE 3250, INDIANAPOLIS, IN, 46204, US

(73) Assignee: Robert Bosch GmbH, Stuttgart (DE)

(21) Appl. No.: 12/329,823

(22) Filed: Dec. 8, 2008

(51) Int. Cl. H03F 1/26; G01D 18/00

(52) U.S. Cl. 702/193; 73/1.01

(57) ABSTRACT

A method and system for testing a MEMS sensor element during operation of a MEMS sensor system in one embodiment includes a test signal generator configured to generate a broad frequency band test signal, and a verification signal substantially identical to the test signal, a microelectrical-mechanical system (MEMS) sensor element operatively connected to the test signal generator for generating a sensor output in response to the test signal, a comparison component configured to generate an evaluation signal output based upon the verification signal and the test signal, and an evaluation circuit operatively connected to the comparison component and configured to identify a mismatch between the verification signal and the sensor output based upon the evaluation signal.

### FIELD

This invention relates to semiconductor devices and particularly to devices incorporating sensor elements.

### BACKGROUND

In the past, micro-electromechanical systems (MEMS) have proven to be effective solutions in various applications due to the sensitivity, spatial and temporal resolutions, and lower power requirements exhibited by MEMS devices. Consequently, MEMS based sensors, such as accelerometers, gyroscopes and pressure sensors, have been developed for use in a wide variety of applications.

Some of the applications incorporating MEMS based sensors are safety critical applications. Specific examples include stability control systems in cars (e.g., ESP) and the sensing of acceleration in airbag systems. For safety critical applications, it is very desirable to have the MEMS sensors tested continuously during operation in order to detect a faulty sensor as soon as possible and warn the user immediately. Typically, however, only portions of the digital circuitry of MEMS sensors are tested during operation and the MEMS sensing element itself is only tested during start-up of the system.

The start-up testing conducted on the MEMS sensing element is usually done by applying a well defined test signal to the mechanics that leads to a displacement of the mechanical proof mass within the MEMS device. The displacement of the proof mass is then measured by the electronic portion of the sensor. The result of this measurement is then compared with two thresholds that define a tolerance range for the device. If the measured signal is within this tolerance range, the system is considered operational and the MEMS sensing element is not re-tested until the next start-up procedure is conducted.

One approach to testing an entire MEMS sensor system, including the MEMS sensing element, is to insert a test-signal into the MEMS sensing element at a frequency above the frequency bandwidth of interest (e.g. about 50 Hz in automotive stability control systems) and below the upper frequency limit of the MEMS sensing element (typically in the kHz range). This approach provides the benefit of creating a response throughout the MEMS sensor system including the MEMS sensing element and the associated electronics since the frequency of the test-signal is within the bandwidth of the MEMS sensing element.

The disadvantage of the foregoing approach, however, is that many MEMS sensor systems are used in environments prone to parasitic vibrations. If the MEMS sensor system is mounted in an environment where vibrations can occur, e.g. in a car, there is a danger that test signals inserted into the system can be masked by parasitic vibrations including, or occurring at, the test signal frequency. In such situations, the MEMS sensing element will react to the combined test-signal/parasitic vibration. Thus, since the amplitude of the parasitic vibration is unknown, it is impossible for the system response to be accurately assessed.

Particularly for safety critical applications, it would be desirable to have the whole system, including the MEMS sensing element, continuously tested. Any such testing should run continuously in the background and should not interfere with the signals to be measured by the device during normal operation of the device. Additionally testing of the device should be robust for the particular environment of the device.

### SUMMARY

In accordance with one embodiment, a method and system for testing a MEMS sensor element during operation of a MEMS sensor system includes a test signal generator configured to generate a broad frequency band test signal, and a verification signal substantially identical to the test signal, a microelectrical-mechanical system (MEMS) sensor element operatively connected to the test signal generator for generating a sensor output in response to the test signal, a comparison component configured to generate an evaluation signal output based upon the verification signal and the test signal, and an evaluation circuit operatively connected to the comparison component and configured to identify a mismatch between the verification signal and the sensor output based upon the evaluation signal.

In accordance with another embodiment, a method of evaluating the response of a sensor element includes configuring a microelectrical-mechanical system (MEMS) sensor element to monitor a condition, applying a broad frequency band test signal to the MEMS sensor element, generating a sensor output based upon the test signal and the monitored condition, filtering the sensor output to remove signal components associated with the test signal, outputting the filtered sensor output to a control circuit, comparing a verification signal to the sensor output, and identifying mismatches between the verification signal and the sensor output based upon the comparison.

In yet another embodiment, a MEMS sensor system includes a test signal generator configured to generate a broad frequency band test signal, and a verification signal substantially identical to the test signal, a microelectrical-mechanical system (MEMS) sensor element operatively connected to a monitored system and the test signal generator for generating a sensor output in response to the test signal and a sensed condition of the monitored system, a comparison component configured to generate an evaluation signal output based upon the verification signal and the test signal, an evaluation circuit operatively connected to the comparison component and configured to identify a mismatch between the verification signal and the sensor output based upon the evaluation signal, and a control circuit operatively connected to the MEMS sensor element for controlling the monitored system in response to the sensed condition.

### BRIEF DESCRIPTION OF THE DRAWINGS

FIG. 1 depicts a schematic circuit diagram of a MEMS sensor system including a built-in self-test in accordance with principles of the present invention;

FIG. 2 depicts a plot of the outputs of various components in the system of FIG. 1 in response to subjecting the MEMS sensor element to a test signal, parasitic vibrations, and a vibration associated with a monitored event;

FIG. 3 depicts a schematic block circuit diagram of a MEMS sensor system including a built-in self-test along with band pass filters and a digital-to-analog converter wherein a digital verification signal is used for comparison with an output of a sensor element.

### DESCRIPTION

For the purposes of promoting an understanding of the principles of the invention, reference will now be made to the embodiments illustrated in the drawings and described in the following written specification. It is understood that no limitation to the scope of the invention is thereby intended. It is further understood that the present invention includes any alterations and modifications to the illustrated embodiments and includes further applications of the principles of the invention as would normally occur to one skilled in the art to which this invention pertains.

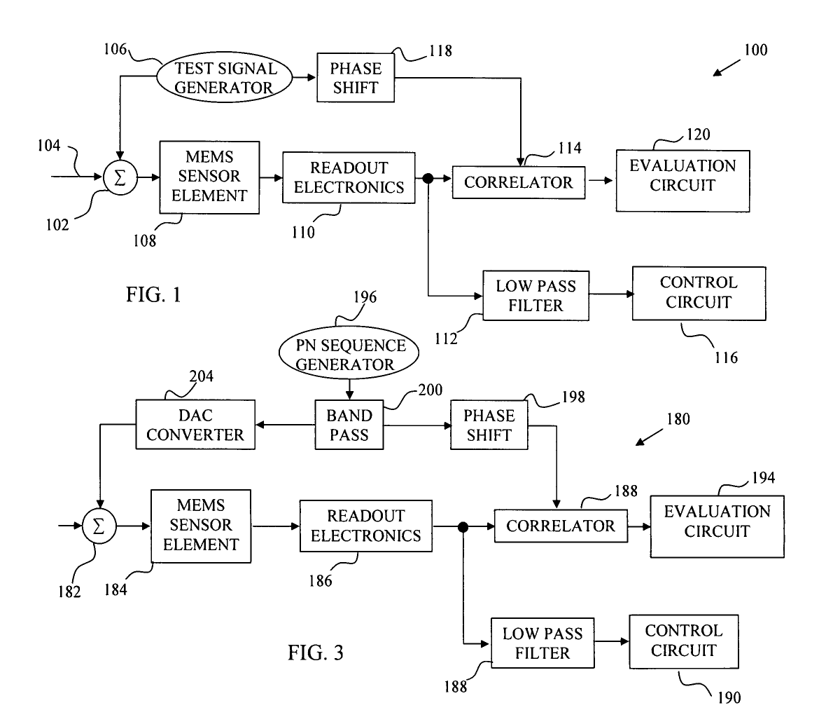

FIG. 1 depicts a block-circuit diagram of a MEMS system 100 with a built-in self-test. The MEMS system 100 is modeled to include a summer 102 that receives input from external vibrations 104 and a test signal generator 106. The output of the summer 102 is provided to a MEMS sensor element 108. The output of the MEMS sensor element 108 is provided to a readout electronics circuit 110 which processes the MEMS sensor element output and provides the processed output to a low pass filter 112 and to a correlator 114. The output of the low pass filter is provided as an input to a control circuit 116 such as an airbag activation controller.

The test signal generator 106, in addition to providing a signal to the summer 102, provides a verification signal to a phase shift circuit 118. The output of the phase shift circuit 118 is provided to the correlator 114. The correlator 114 receives input from the readout electronics 110 and the phase shift circuit 118 and provides an output based upon the inputs to an evaluation circuit 120.

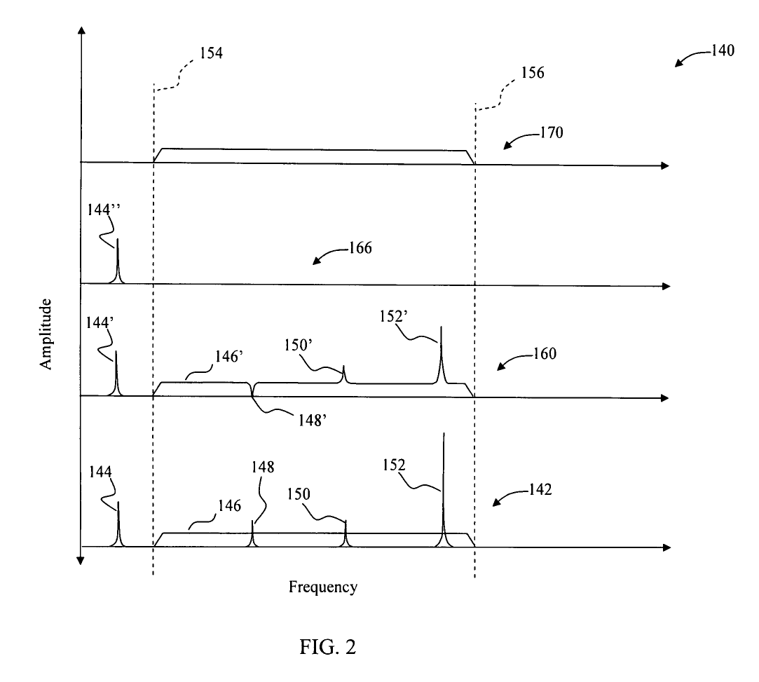

In operation, the test signal generator 106 is used to vibrate the MEMS sensor element at predetermined frequencies and with a known energy. By way of example, FIG. 2 depicts a family of plots 140 of exemplary signals within the MEMS system 100. The plot 142 of the family of plots 140 represents the individual signal components applied to the MEMS system 100 showing the frequencies and amplitudes of the various components. In other words, the plot 142 shows the output of the summer 102.

The plot 142 includes a monitored event 144, a test signal 146, and parasitic vibrations 148, 150, and 152. The monitored event 144 is a vibration which is used to initiate an output of the control circuit 116. The high frequency cutoff 154 of the low pass filter 112 is set at a frequency higher than the frequency of the monitored event 144.

The test signal 146 is a broad frequency spectrum signal generated by the test signal generator 106. The test signal 146 is shown with a uniform amplitude over a wide frequency spectrum. In alternative embodiments, sets of discreet frequencies within a frequency band may be generated, with the same or different amplitudes. The frequency range of the test signal 146 is selected to begin at a frequency higher than the high frequency cutoff 154 and below the upper frequency response limit 156 of the MEMS sensor element 108. In one embodiment, the test signal generator 106 is a pseudo random noise (PRN) generator with an internal band pass filter which generates a complex waveform based upon random signals generated within a predetermined frequency spectrum established by the band pass filter.

The parasitic vibrations 148, 150, and 152 reflect vibrations to which the MEMS sensor element 108 has been exposed which are not necessarily associated with a monitored event. The parasitic vibrations 148, 150, and 152, which are components of the external vibrations 104, are vibrations which are not intended to produce an output by the control circuit 116.

In response to the vibrations to which the MEMS sensor element 108 is exposed from all sources, the MEMS sensor element 108, which in one embodiment includes a proof mass, produces an output indicative of the vibrations to which the MEMS sensor element 108 has been exposed. By way of example, the MEMS sensor may incorporate piezoelectric materials so as to generate an electrical signal that is proportional to the movement of the proof mass.

The output of the MEMS sensor element 108 is received by the readout electronics 110. The readout electronics 110 conditions the received signal. Such conditioning may include amplification of the signal, removal of noise, etc. A signal associated with the output of the MEMS sensor element 108 is then provided by the readout circuit 110 to the correlator 114 and to the low pass filter 112.

The plot 160 of FIG. 2 represents the output of the readout electronics 110. The output includes features 144′, 146′, 148′, 150′, and 152′, associated with the monitored event 144, the test signal 146, and the parasitic vibrations 148, 150, and 152, respectively. In this example, the parasitic vibration 148 is out of phase with the test signal 146. Accordingly, the feature 148′ exhibits a reduced amplitude in the output while the vibrations 150 and 152 are closer in phase to the test signal 146, resulting in increased amplitude of the output as shown by the features 150′ and 152′.

As described above with reference to FIG. 2, the low pass filter 112 has a high frequency cutoff 154 that is lower than the frequencies which are generated by the test signal generator 106. Accordingly, any signal component associated with the output of the MEMS sensor element 108 which is based upon a test signal is not passed by the low pass filter 112. Likewise, parasitic vibrations which are higher than the high frequency cutoff 152 are not passed by the low pass filter 112. Rather, only signals associated with the output of the MEMS sensor element 108 that result from vibrations in the frequency range of interest, such as the signal 144′, are passed to the control circuit 116. The control circuit 116 then reacts to the output of the low pass filter 112, such as by controlling deployment of an airbag.

The output of the low pass filter 112 is represented in FIG. 2 by plot 166. As shown by plot 166, the features associated with the test signal 146, and the parasitic vibrations 148, 150, and 152 (components 146′, 148′, 150′, and 152′) are not passed by the low pass filter 112. A component 144″, associated with the component 144′ and the monitored event 144, however, is passed to the control circuit 116.

The correlator 114 also receives the signal associated with the output of the MEMS sensor element 108 from the readout electronics 110 (plot 160). The correlator 114 also receives a verification signal, represented in plot 170, which originated with the test signal generator 106 and passed through the phase shift circuit 118.

More specifically, the test signal generator 106 generates a verification signal that is identical to the test signal. If desired, the same signal may be split into a test signal and a verification signal. The phase shift circuit 118 compensates the verification signal for the frequency dependent phase shift experienced by the test signal due to the frequency dependent behavior of the MEMS sensing element 108 and the readout electronics 110.

Accordingly, the verification signal, shown in the plot 170 of FIG. 2, which is received by the correlator 114, is identical to a signal that should be generated by the readout electronics based upon the test signal generated by the test signal generator 106, if the MEMS sensor element 108 and the readout electronics 110 are functioning properly and there is no interference with the operation of the MEMS system 100, such as parasitic vibrations.

The correlator 114 performs a cross-correlation between the sensor output (plot 160) and the verification signal (plot 170). Based upon the correlation analyses, the correlator 114 outputs a number which is a measure of the likelihood that the test signal is present in the readout electronics 110 output (plot 160). If the output of the correlator 114 is higher, the probability that the test signal (or test sequence) is represented in the readout electronics 110 output (plot 160) is also higher.

Subsequently, the evaluation circuit 120 compares the numerical output of the correlator 114 to a predetermined threshold to give a “TRUE” or “FALSE” output. The output may be used to provide an alarm. Additionally, the threshold may be set to require a higher likelihood in a particular application.

The MEMS system 100 is thus capable of providing continuous verification of the operating capability of the components within the MEMS system 100 during operation of the system 100, with the exception of the low pass filter 112, without adversely impacting the ability of the MEMS system 100 to monitor a condition. The operational status of the low pass filter 112, however, can be verified using methods known in the field of fault tolerant system design.

Another embodiment of a MEMS system 180 is depicted in FIG. 3. The MEMS system 180 is modeled as including a summer 182, a MEMS sensor element 184, readout electronics 186, a low pass filter 188, a control circuit 190, a correlator 192, an

The MEMS system 180, which in one embodiment is a mixed-signal capacitive MEMS accelerometer, and the components therein, differ from the MEMS system 100 and the components therein in various ways. One difference is that the test signal, after passing through a band pass filter 200 and being split from a verification signal, is passed to a digital-to-analog (DAC) converter 204 that is provided between the band pass filter 200 and the correlator 182. Furthermore, the readout electronics 186 also include a DAC.

The differences in the MEMS system 180 allow the test signal generated by the PN sequence generator 196 to be filtered by the band pass filter 200 to limit the frequency spectrum applied to the MEMS sensing element 184 to a desired frequency spectrum.

Additionally, the test signal is generated in the digital domain in the MEMS system 180. Accordingly, once the test signal is filtered, the signal is fed to the DAC 204. In one embodiment, the DAC 204 is a DAC with a single bit output stream. Accordingly, the test signal applied to the MEMS sensing element 184 is a sequence of pulses. In this example there are only two kinds of pulses and the logic value of the DAC output determines which of the two pulses is applied to the sensing element 184. This provides a highly linear digital-to-analog conversion and a precise injection of the test signal into the MEMS sensing element 184.

While the invention has been illustrated and described in detail in the drawings and foregoing description, the same should be considered as illustrative and not restrictive in character. It is understood that only the preferred embodiments have been presented and that all changes, modifications and further applications that come within the spirit of the invention are desired to be protected.

1. A MEMS sensor system comprising:
a test signal generator configured to generate a broad frequency band test signal, and a verification signal substantially identical to the test signal;
a microelectrical-mechanical system (MEMS) sensor element operatively connected to the test signal generator for generating a sensor output in response to the test signal;
a comparison component configured to generate an evaluation signal output based upon the verification signal and the test signal; and
an evaluation circuit operatively connected to the comparison component and configured to identify a mismatch between the verification signal and the sensor output based upon the evaluation signal.

2. The system of claim 1, wherein the test signal generator comprises a pseudo random noise generator, the system further comprising:
a band pass filter operably positioned between the test signal generator and the MEMS sensor element to limit the frequency band of the test signal.

3. The system of claim 2, further comprising:
a digital to analog converter, operably positioned between the band pass filter and the MEMS sensor element to convert a digital signal from the test signal generator to an analog signal.

4. The system of claim 1, further comprising:
a readout circuit operably connected to the MEMS sensor element and the comparison component; and
a phase shifting circuit operably connected to the test signal generator and the comparison component.

5. The system of claim 4, further comprising:
a band pass filter operably positioned between the test signal generator and both the MEMS sensor element and the phase shifting circuit, to limit the frequency band of the test signal.

6. The system of claim 4, further comprising:
a low pass filter operably connected to the readout circuit, the low pass filter configured with a high frequency cutoff that is lower than the frequency band of the test signal; and
a control circuit operably connected to the low pass filter.

7. A method of evaluating the response of a sensor element comprising:
configuring a microelectrical-mechanical system (MEMS) sensor element to monitor a condition;
applying a broad frequency band test signal to the MEMS sensor element;
generating a sensor output based upon the test signal and the monitored condition;
filtering the sensor output to remove signal components associated with the test signal;
outputting the filtered sensor output to a control circuit;
comparing a verification signal to the sensor output; and
identifying mismatches between the verification signal and the sensor output based upon the comparison.

8. The method of claim 7, wherein comparing comprises:
subtracting the verification signal from the sensor output.

9. The method of claim 7, wherein comparing comprises:
correlating the verification signal with the sensor output;

10. The method of claim 9, further comprising:
comparing the mismatches with a threshold.

11. The method of claim 7, further comprising:
generating the broad frequency band test signal with a pseudo random noise generator; and
filtering the broad frequency band test signal with a band pass filter prior to applying the broad frequency band test signal to the MEMS sensor element.

12. The method of claim 11, further comprising:
converting a filtered broad frequency band digital test signal to a filtered broad frequency band analog test signal.

13. The method of claim 7, further comprising:
phase shifting the verification signal prior to comparing the verification signal to the sensor output.

14. A MEMS sensor system comprising:
a test signal generator configured to generate a broad frequency band test signal, and a verification signal substantially identical to the test signal;
a microelectrical-mechanical system (MEMS) sensor element operatively connected to a monitored system and the test signal generator for generating a sensor output in response to the test signal and a sensed condition of the monitored system;
a comparison component configured to generate an evaluation signal output based upon the verification signal and the test signal;
an evaluation circuit operatively connected to the comparison component and configured to identify a mismatch between the verification signal and the sensor output based upon the evaluation signal; and
a control circuit operatively connected to the MEMS sensor element for controlling the monitored system in response to the sensed condition.

15. The system of claim 14, wherein the MEMS sensor element comprises a proof mass.

16. The system of claim 14, wherein the monitored system is an airbag deployment system.

17. The system of claim 14, wherein the test signal generator comprises a pseudo random noise generator, the system further comprising:
a band pass filter operably positioned between the test signal generator and the MEMS sensor element to limit a frequency spectrum of the broad frequency band test signal.

18. The system of claim 17, further comprising:
a digital to analog converter, operably positioned between the band pass filter and the MEMS sensor element to convert a digital signal from the test signal generator to an analog signal.

19. The system of claim 1, further comprising:
a readout circuit operably connected to the MEMS sensor element and the comparison component; and
a phase shifting circuit operably connected to the test signal generator and the comparison component.

20. The system of claim 19, further comprising:
a band pass filter operably positioned between the test signal generator and both the MEMS sensor element and the phase shifting circuit, to limit the frequency band of the test signal.
